(19) United States
(12) Patent Application Publication
(10) Pub. No.: US 2026/0150419 A1
(43) Pub. Date: May 28, 2026

(54) LENS ASSEMBLY

(71) Applicant: Asia Optical Co., Inc., Taichung (TW)

(72) Inventors: Hsi-Ling Chang, Taichung (TW); Chien-Hung Chen, Taichung (TW)

(21) Appl. No.: 19/033,597

(22) Filed: Jan. 22, 2025

(30) Foreign Application Priority Data
Nov. 25, 2024 (TW) 113145378

(51) Int. Cl. H10F 39/00; B82Y 20/00

(52) U.S. Cl. CPC H10F 39/8063; B82Y 20/00

(57) ABSTRACT

A lens assembly, in sequence from an object side to an image side, includes an optical element including a plurality of pairs of nanostructures, and an image sensing element including a plurality of pairs of pixel areas. Each pair of nanostructures includes a first view nanostructure and a second view nanostructure. Each pair of pixel areas includes a first view pixel area and a second view pixel area. The first view nanostructure guides a light from the object to form an image of the object on the first view pixel area and the second view nanostructure guides a light from the object to form an image of the object on the second view pixel area.

### BACKGROUND OF THE INVENTION

### Field of the Invention

The invention relates to a lens assembly.

### Description of the Related Art

How to significantly reduce the volume and weight of an imaging lens while maintaining good optical performance is an ultimate goal pursued by optical designers. Nowadays, it always has the requirement to reduce the size and weight of the lenses used in mobile phones and AR/VR head-mounted devices. It's more and more difficult for the conventional lenses to meet the present requirement, and an innovative imaging lens is created by this invention. This invention significantly reduces the size and weight of the lenses assembly while it maintains good optical performance.

### BRIEF SUMMARY OF THE INVENTION

Therefore, the main purpose of the present invention is to provide a lens assembly that can significantly reduce its size and weight as well as keep good optical performance.

The present invention provides a lens assembly, which includes an optical element and an image sensing element in sequence from an object side to an image side. The optical element includes a plurality of pairs of nanostructures. The image sensing element includes a plurality of pairs of pixel areas. Each pair of nanostructures includes a first view nanostructure and a second view nanostructure. Each pair of pixel areas includes a first view pixel area and a second view pixel area. The first view nanostructure guides a light from the object to form an image of the object on the first view pixel area and the second view nanostructure guides a light from the object to form an image of the object on the second view pixel area.

The first view nanostructure and the second view nanostructure are adjacent to each other to form a pair of nanostructures. All the pairs of nanostructures are arranged in sequence to form a plurality of pairs of nanostructures.

The first view pixel area and the second view pixel area are adjacent to each other to form a pair of pixel areas. All the pairs of pixel areas are arranged in sequence to form a plurality of pairs of pixel areas.

The first view pixel area and the second view pixel area are spaced at regular interval to form a pair of pixel areas. All pairs of pixel areas are arranged in periodic order to form a plurality of pairs of pixel areas.

The first view nanostructure and the second view nanostructure are spaced at regular interval to form a pair of nanostructures. All pairs of nanostructures are arranged in periodic order to form a plurality of pairs of nanostructures.

The first view pixel area and the second view pixel area are spaced at regular interval to form a pair of pixel areas. All pairs of pixel areas are arranged in periodic order to form a plurality of pairs of pixel areas.

The pattern or structure of first view nanostructure and the second view nanostructure is the same or different. The size of the first view nanostructure and the second view nanostructure is the same size or different.

The optical element includes a first surface facing the object side and a second surface facing the image side. The image sensing element is a sensor including a sensing surface facing the object side and a plurality of pairs of pixel areas is formed on the sensing surface. After a light from the object side passing through the first view nanostructure is guided to the first view pixel area and a light from the object side passing through the second view nanostructure is guided to the second view pixel area.

The first surface of the optical element is divided into a first incident area facing the object side and a second incident area facing the object side. The image sensing element is divided into a first sensing area facing the object side and a second sensing area facing the object side. The first incident area and the second incident area are divided into a total number of “a” rows in the horizontal direction and divided into a total number of “b” columns in the vertical direction so that a total of incident areas are “a” times “b”, wherein “a” is a positive integer greater than or equal to 2, “b” is a positive integer greater than or equal to 1, or “a” is a positive integer greater than or equal to 1, “b” is a positive integer greater than or equal to 2, and each incident area includes its nanostructure. The first sensing area and the second sensing area are divided into a total number of rows which equal to the number of rows of the incident area in the horizontal direction and divided into a total number of columns which equal to the number of columns of the incident area.

After the light from the object is incident on the incident area of the m-th row and the n-th column, it is guided to the corresponding sensing area of the m-th row and the n-th column, wherein the “m” is a positive integer from 1 to a, and the “n” is a positive integer from 1 to b.

After the light from the object is incident on the incident area of the m-th row and the (2n-1)th column, it is guided to the sensing area of the m-th row and n-th column, the “m” is a positive integer from 1 to a, and the “n” is a positive integer from 1 to b/2. After the light from the object is incident on the incident area of the m-th row and the 2n-th column, it is guided to the sensing area of the m-th row and (b/2+n)th column, the “m” is a positive integer from 1 to a, and the “n” is a positive integer from 1 to b/2.

The number of columns in the incident area is equal to the number of columns in the sensing area, the number of rows in the incident area is equal to the number of rows in the sensing area.

The pattern of plurality of pairs of nanostructures is selected from at least one of the group of rectangular, circular columns, elliptical, rhombus, cross, quadrilateral, pentagonal, hexagonal, octagonal, asymmetrical, the cross-sectional shape of an oak barrel.

The shape of the plurality of pairs of microstructures may all be the same.

The shape of the plurality of pairs of nanostructures is partially the same and the shape of other pairs of nanostructures is different.

The arrangement of the patterns is in sequential order, in a staggered order, or in random order.

The arrangement of the patterns is partially in sequential order and partially in staggered order.

The arrangement of the patterns is partially in sequential order and partially in random order.

The arrangement of the patterns is partially in sequential order, partially in staggered order, and partially in random order.

The plurality of pairs of nanostructures are disposed on the first surface and the second surface, or the plurality of pairs of nanostructures are disposed either on the first surface or on the second surface.

The optical element includes a first surface facing an object side and a second surface facing an image side, at least one of the first and second surfaces is divided into a plurality of rows in the horizontal direction and a plurality of columns in the vertical direction so as to form a plurality of pair of nanostructures, wherein each pair of nanostructures includes a first view nanostructure and a second view nanostructure. The sensing surface of the image sensing element is divided into a plurality of rows in the horizontal direction and a plurality of columns in the vertical direction so as to form a plurality of pair of pixel areas, wherein each pair of pixel areas includes a first view pixel area and a second view pixel area. After the light from the object is incident on the plurality of pair of nanostructures, the light is guided to the first view pixel area by the first view nanostructure and the light is guided to the second view pixel area by the second view nanostructure.

The first view pixel area and the second view pixel area are adjacent to each other to form a pair of pixel areas. At least one of the total number of rows and the total number of columns is an even integer.

The first view pixel area and the second view pixel area are spaced at regular interval to form a pair of pixel areas. At least one of the total number of rows and the total number of columns is an even integer.

The invention can be more fully understood by the subsequent detailed description and embodiments with reference to the accompanying drawings.

### BRIEF DESCRIPTION OF THE DRAWINGS

FIG. 1 is a schematic side view of the lens and sensor of the first embodiment of the lens assembly according to the present invention;

FIG. 2 is a schematic diagram of the lens and sensor of the lens assembly according to the first embodiment of the present invention;

FIG. 3 is a schematic diagram of the configuration and optical path of the lens assembly according to the first embodiment of the present invention;

FIG. 4 is a schematic diagram of the configuration and optical path of the lens assembly according to the second embodiment of the present invention;

FIG. 5 is a schematic diagram of the lens and sensor of the lens assembly according to the second embodiment of the present invention;

FIG. 6 is a schematic diagram of the lens and sensor of the lens assembly according to the third embodiment of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

The present invention provides a lens assembly, which sequentially includes from an object side to an image side: an optical element including a plurality of pairs of nanostructures; and an image sensing element including a plurality of pairs of pixel areas. Each pair of nanostructures includes a first view nanostructure and a second view nanostructure. The image of first view of the object is formed on the first view pixel area by the first view nanostructure. The image of second view of the object is formed on the second view pixel area by the second view nanostructure.

In the following embodiments, the lens is the optical element, and the sensor is the image sensing element which includes a plurality of pixels. The optical element has a plurality of pairs of nanostructures and each nanostructure is a lens at the nanoscale. In the invention, for example, each lens at the nanoscale marked L11, L12, L13, L14, L11″, L12″, L13″, L14″ . . . are the first view nanostructures formed on the first surface, and each lens at the nanoscale marked R11, R12, R13, R14, R11″, R12″, R13″, R14″ . . . are the second view nanostructures formed on the first surface. In the invention, for example, the pixel area marked L11′, L12′, L13′, L14′, L11′″, L12″, L13″, L14″ . . . are the first view pixel areas, and the pixel area marked R11′, R12′, R13′, R14′, R11″, R12″′, R13″, R14″ . . . are the second view pixel areas.

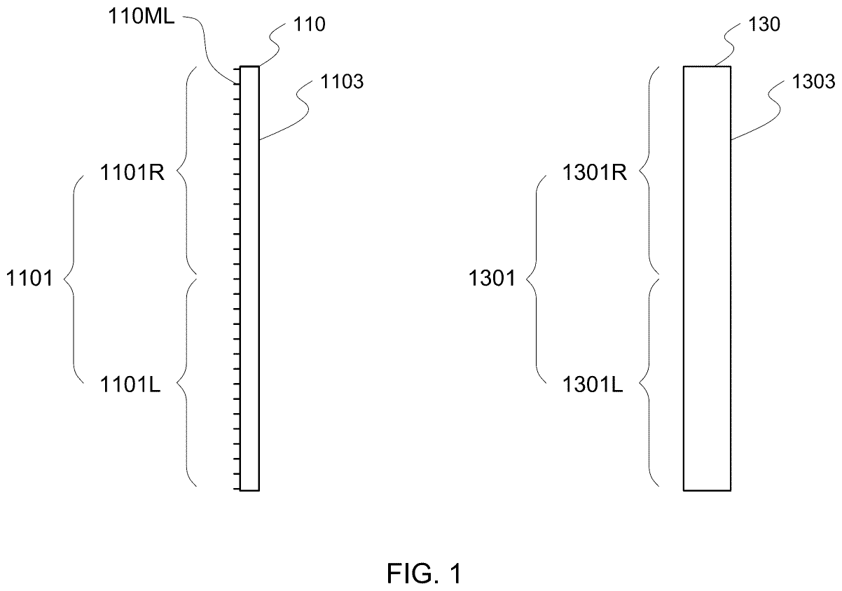

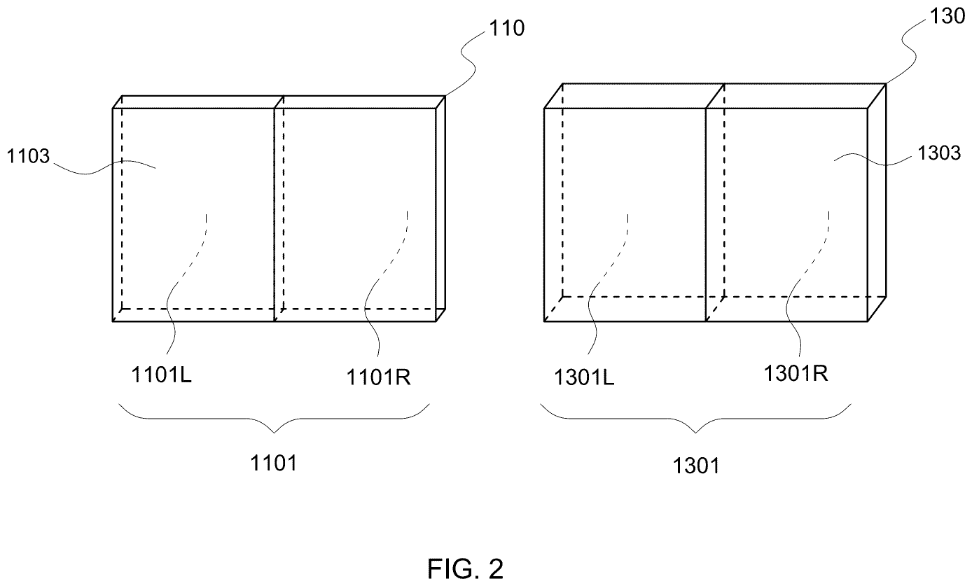

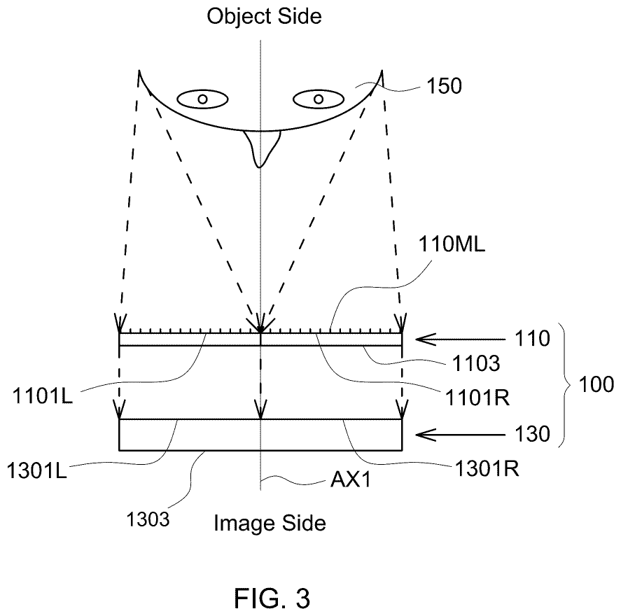

The first embodiment of the lens assembly of the present invention is described below. Please refer to FIGS. 1, 2 and 3. FIG. 1 is a schematic side view of the lens and sensor of the first embodiment of the lens assembly according to the present invention. FIG. 2 is a schematic diagram of the lens and sensor of the lens assembly according to the first embodiment of the present invention. The optical element including a plurality of pairs of nanostructures may be the metalens, and all the embodiments of the optical element in the specification of the invention will be described with metalens as the example. The metalens 110 in FIG. 2 includes a first surface 1101 and a second surface 1103 and it is viewed from the second surface 1103 to the first surface 1101. The first surface 1101 includes a plurality of nanostructures 110ML at the nanoscale, and the first surface 1101 is divided into a first incident area 1101L and a second incident area 1101R. The first incident area 1101L and the second incident area 1101R respectively include a plurality of nanostructures 110ML. When the light from an object is incident on the nanostructures 110ML, each nanostructure will change the direction of light propagation away from its original direction. According to actual requirement, each of the nanostructures 110ML on the first incident area 1101L and each of the nanostructures 110ML on the second incident area 1101R can be designed to direct the light in any desired direction. The pattern or structure of nanostructures 110ML can be rectangular, circular, elliptical, rhombus, cross, or polygonal. The nanostructures 110ML can all be the same pattern or structure, or part of the nanostructures 110ML can be the same pattern or structure and the other part of the nanostructures 110ML have different patterns or structure. Alternatively, the nanostructures 110ML may include at least two different patterns. The image sensing element 130 in FIG. 2 includes a sensing surface 1301 and a bottom surface 1303, and it is visually viewed from the bottom surface 1303 to the sensing surface 1301. The sensing surface 1301 is further divided into a first view pixel area 1301L and a second view pixel area 1301R. Please refer to FIG. 3. FIG. 3 is a schematic diagram of the configuration and optical path of the lens assembly according to the first embodiment of the present invention. The lens assembly 100, sequentially from an object side to an image side along an axis AX1, includes a metalens 110 and an imaging sensing element 130. The first surface 1101 of the metalens 110 faces toward the object side and the second surface 1103 faces toward the image side. The first surface 1101 is further divided into a first incident area 1101L and a second incident area 1101R by the axis AX1. The sensing surface 1301 of the sensor 130 faces the object side. The sensing surface 1301 is further divided into a first view pixel area 1301L and a second view pixel area 1301R by the axis AX1. The first incident area 1101L corresponds to the first view pixel area 1301L, and the first incident area 1101L and the first view pixel area 1301L are located on one side of the axis AX1. The second incident area 1101R corresponds to the second view pixel area 1301R, and the second incident area 1101R and the second view pixel area 1301R are located on the other side of the axis AX1. After the light from an object 150 enters the first incident area 1101L, the nanostructures 110ML of the first incident area 1101L are designed to guide the light to the first view pixel area 1301L for forming the first view image of the object. Likewise, the nanostructures 110MR of the second incident area 1101R are designed to guide the light to the second view pixel area 1301R for forming the second view image of the object. In the first embodiment of the invention, for example, the first view pixel area 1301L cooperates with the first incident area 1101L to form a left view image of the object 150, and the second view pixel area 1301R cooperates with the second incident area 1101R to form a right view image of the object 150. Finally, the left view image and the right view image together form a stereoscopic image of the object having the feature of depth perception, which is similar to the eyes of humans. The above description does not limit the scope of the claims in the present invention. Similarly, the first view pixel area 1301L cooperates with the first incident area 1101L to form an upper view image of the object 150, and the second view pixel area 1301R cooperates with the second incident area 1101R to form a lower view image of the object 150.

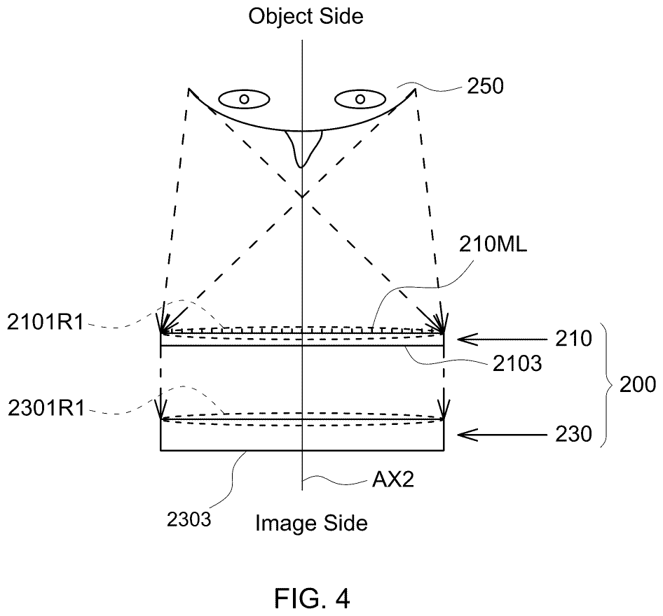

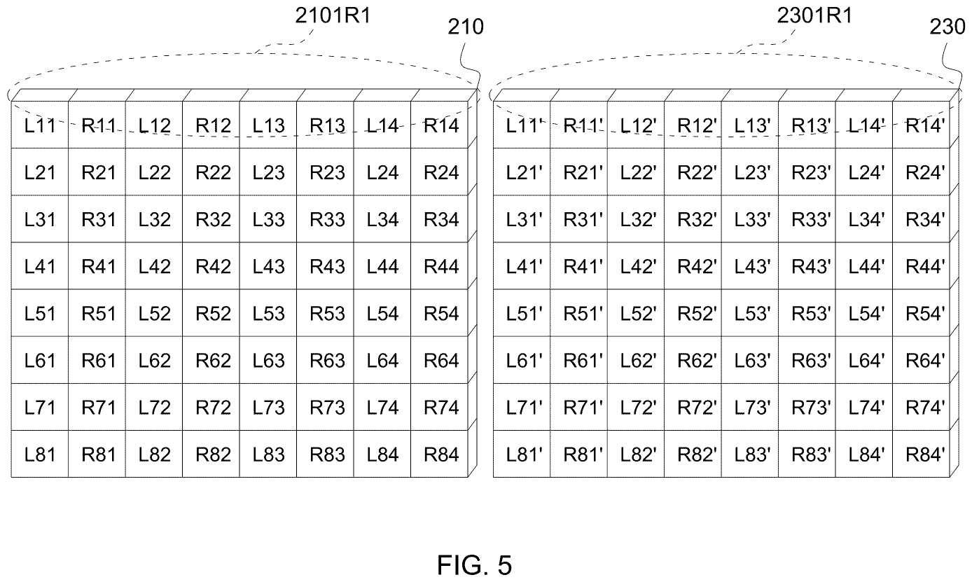

The second embodiment of the lens assembly of the present invention is described below. Please refer to FIGS. 4 and 5. FIG. 4 is a schematic diagram of the configuration and optical path of the lens assembly according to the second embodiment of the present invention. FIG. 5 is a schematic diagram of the lens and sensor of the lens assembly according to the second embodiment of the present invention. The metalens 210 in FIG. 5 includes a first surface 2101 (facing the object side) and a second surface 2103 (facing the image side) and it is viewed from the second surface 2103 to the first surface 2101. The image sensing element 230 in second embodiment includes a sensing surface 2301 (facing the object side) and a bottom surface 2303 (facing the image side), and it is visually viewed from the bottom surface 2303 to the sensing surface 2301. The first surface 2101 of the metalens 210 includes a plurality of nanostructures 210ML at the nanoscale, which are divided into even number of rows of incident areas in the horizontal direction, and are divided into the same even number of columns of incident areas in the vertical direction. In the example of second embodiment, the first surface is divided into 8 rows of incident areas in the horizontal direction, and the first surface is divided into 8 columns of incident areas in the vertical direction. Therefore, the first surface is divided into a total of 64 (=8×8) incident areas, and each incident area includes its nanostructures 210ML. As shown in FIG. 5, the first row 2101R1 of the first surface 2101 of the metalens 210, which is viewed from the second surface 2103 to the first surface 2101 (facing the object side) and is marked from left to right and top to bottom, includes: nanostructure L11 at first row and first column, nanostructure R11 at first row and second column, nanostructure L12 at first row and third column, nanostructure R12 at first row and fourth column, nanostructure L13 at first row and fifth column, nanostructure R13 at first row and sixth column, nanostructure L14 at first row and seventh column and nanostructure R14 at first row and eighth column. In the end, the eighth row 2101R8 includes: nanostructure L81 at the eighth row and first column, nanostructure R81 at eighth row and second column, nanostructure L82 at eighth row and third column, nanostructure R82 at eighth row and fourth column, nanostructure L83 at eighth row and fifth column, nanostructure R83 at eighth row and sixth column, nanostructure L84 at eighth row and seventh column and nanostructure R84 at eighth row and eighth column. As a result, the nanostructure Lmn (m and n are positive integer) formed on the first surface 2101 is located at m-th row and (2n-1)th column, and the nanostructure Rmn (m and n are positive integer) formed on the first surface is located at m-th row and (2n)th column; wherein m is a positive integer from 1 to a, n is a positive integer from 1 to b/2, a is total number of rows, b is the total number of columns, and both a and b are even integer. When the light from an object is incident on the first surface of the metalens, the propagation of light will be guided to different direction by the plurality of nanostructures 210ML. Depending on actual requirement of the design, each of the plurality of nanostructures 210ML can be designed to guide the light in any desired direction. The image sensing element 230 includes a sensing surface 2301 and a bottom surface 2303. The sensing surface 2301 is further divided into a plurality of pixel areas; wherein, in the second embodiment of the invention, the number of rows of the pixel areas is equal to the number of rows of the nanostructures and the number of columns of the pixel areas is equal to the number of columns of the nanostructures. In the example of second embodiment, the sensing surface is divided into 8 rows in the horizontal direction, and the sensing surface is divided into 8 columns in the vertical direction. Therefore, the sensing surface is divided into a total of 64 (=8×8) pixel areas. As shown in FIG. 5, the first row 2301R1 of the sensing surface 2301 of the image sensing element 230, which is viewed from the bottom surface 2303 to the sensing surface 2301 (facing the object side) and is marked from left to right and top to bottom, includes: pixel area L11′ at first row and first column, pixel area R11′ at first row and second column, pixel area L12′ at first row and third column, pixel area R12′ at first row and fourth column, pixel area L13′ at first row and fifth column, pixel area R13′ at first row and sixth column, pixel area L14′ at first row and seventh column and pixel area R14′ at first row and eighth column. In the end, the eighth row 2301R8 of the sensing surface 2301 includes: pixel area L81′ at the eighth row and first column, pixel area R81′ at eighth row and second column, pixel area L82′ at eighth row and third column, pixel area R82′ at eighth row and fourth column, pixel area L83′ at eighth row and fifth column, pixel area R83′ at eighth row and sixth column, pixel area L84′ at eighth row and seventh column and pixel area R84′ at eighth row and eighth column. As a result, the pixel area Lmn′ (m and n are positive integer) formed on the sensing surface 2301 is located at m-th row and (2n-1)th column, and the pixel area Rmn′ (m and n are positive integer) formed on the sensing surface 2301 is located at m-th row and (2n)th column; wherein m is a positive integer from 1 to c, n is a positive integer from 1 to d/2, c is total number of rows, d is the total number of columns, and both c and d are even integer. When the lens assembly in the second embodiment forms an image of an object 250, the optical path of the light from the object 250 and passing through the metalens 210 is different from the optical path of the light from the object 150 and passing through the metalens 110. In the second embodiment of the invention, the light from the object 250 and passing through the nanostructure L11 of the metalens 210 is guided to the pixel area L11′ at first row and first column on the sensing surface, the light from the object 250 and passing through the nanostructure R11 of the metalens 210 is guided to the pixel area R11′ at first row and second column on the sensing surface, the light from the object 250 and passing through the nanostructure L12 of the metalens 210 is guided to the pixel area L12′ at first row and third column on the sensing surface, the light from the object 250 and passing through the nanostructure R12 of the metalens 210 is guided to the pixel area R12′ at first row and fourth column on the sensing surface, the light from the object 250 and passing through the nanostructure L13 of the metalens 210 is guided to the pixel area L13′ at first row and fifth column on the sensing surface, the light from the object 250 and passing through the nanostructure R13 of the metalens 210 is guided to the pixel area R13′ at first row and sixth column on the sensing surface, the light from the object 250 and passing through the nanostructure L14 of the metalens 210 is guided to the pixel area L14′ at first row and seventh column on the sensing surface, and the light from the object 250 and passing through the nanostructure R14 of the metalens 210 is guided to the pixel area R14′ at first row and eighth column on the sensing surface. In the end, the light from the object 250 and passing through the nanostructure L81 of the metalens 210 is guided to the pixel area L81′ at eighth row and first column on the sensing surface, the light from the object 250 and passing through the nanostructure R81 of the metalens 210 is guided to the pixel area R81′ at eighth row and second column on the sensing surface, the light from the object 250 and passing through the nanostructure L82 of the metalens 210 is guided to the pixel area L82′ at eighth row and third column on the sensing surface, the light from the object 250 and passing through the nanostructure R82 of the metalens 210 is guided to the pixel area R82′ at eighth row and fourth column on the sensing surface, the light from the object 250 and passing through the nanostructure L83 of the metalens 210 is guided to the pixel area L83′ at eighth row and fifth column on the sensing surface, the light from the object 250 and passing through the nanostructure R83 of the metalens 210 is guided to the pixel area R83′ at eighth row and sixth column on the sensing surface, the light from the object 250 and passing through the nanostructure L84 of the metalens 210 is guided to the pixel area L84′ at eighth row and seventh column on the sensing surface, and the light from the object 250 and passing through the nanostructure R84 of the metalens 210 is guided to the pixel area R84′ at eighth row and eighth column on the sensing surface. As a result, the light from the object 250 and passing through the nanostructure located at the m-th row and n-th column is guided to the pixel area at m-th row and n-th column on the sensing surface; wherein m and n are positive integer. In the second embodiment, m is an integer selected from one to eight and n is an integer selected from one to eight. Furthermore, in the second embodiment of the invention, the first surface of the metalens and the sensing surface are respectively divided into incident areas and sensing areas in matrix form, and the number of rows and columns of the matrix is an even number. After the light from an object is incident on and passing through the incident areas in matrix form, the light will be guided to each of the plurality of pairs of pixel areas in the sequence from left to right and top to down by each of the plurality of pairs of nanostructures correspondingly. Each pair of nanostructures respectively receives the left view at the corresponding position and right view at the corresponding position of light from the object, and then the left view at the corresponding position and right view at the corresponding position of light from the object and passing such pair of nanostructures will form the left view and right view image at the corresponding position of the object by a corresponding pair of pixel areas. Specifically, pixel area L11′ at first row and first column on the sensing surface will form the left view image at the corresponding position of the object, and pixel area R11′ at first row and second column on the sensing surface will form the right view image at the corresponding position of the object. Pixel area L12′ at first row and third column on the sensing surface will form the left view image at the corresponding position of the object, and pixel area R12′ at first row and fourth column on the sensing surface will form the right view image at the corresponding position of the object. Similarly, pixel area L81′ at eighth row and first column on the sensing surface will form the left view image at the corresponding position of the object, and pixel area R81′ at eighth row and second column on the sensing surface will form the right view image at the corresponding position of the object. By that analogy, from the first row on the sensing surface to the eighth row on the sensing surface, each two columns of pixel areas is grouped to respectively form the left view image at the corresponding position and the right view image at the corresponding position. Therefore, the left view image at the corresponding position and the right view image at the corresponding position produced by each pair of pixel areas together form a stereoscopic image of the object having the feature of depth perception. The above description in the second embodiment does not limit the scope of the claims in the present invention. Similarly, each pair of pixel areas cooperates with the corresponding pair of nanostructures to form an upper view image and a lower view image of the object.

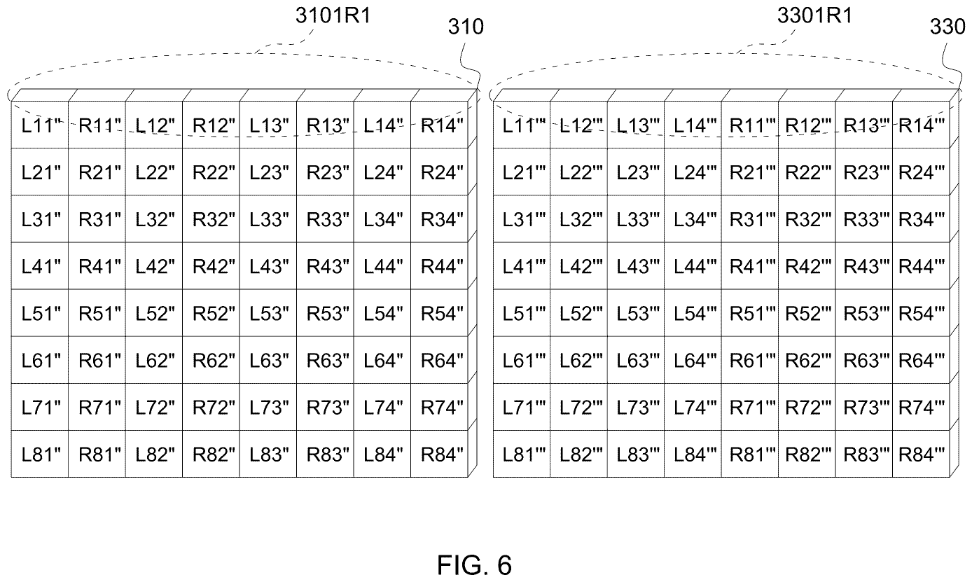

The third embodiment of the lens assembly of the present invention is described below. Please refer to FIG. 6, and FIG. 6 is a schematic diagram of the lens and sensor of the lens assembly according to the third embodiment of the present invention. The metalens 310 in FIG. 6 includes a first surface (facing the object side) including a plurality of nanostructures (not shown in this Figure) and a second surface (facing the image side) and it is viewed from the second surface to the first surface. The image sensing element 330 in third embodiment includes a sensing surface (facing the object side) and a bottom surface (facing the image side), and it is visually viewed from the bottom surface to the sensing surface. The first surface of the metalens 310 includes a plurality of nanostructures at the nanoscale, which are divided into even number of rows of incident areas in the horizontal direction, and are divided into the same even number of columns of incident areas in the vertical direction. In the example of third embodiment, the first surface is divided into 8 rows of incident areas in the horizontal direction, and the first surface is divided into 8 columns of incident areas in the vertical direction. Therefore, the first surface is divided into a total of 64 (=8×8) incident areas, and each incident area includes its nanostructures. As shown in FIG. 6, the first row 3101R1 of the first surface of the metalens 310, which is viewed from the second surface to the first surface (facing the object side) and is marked from left to right and top to bottom, includes: nanostructure L11″ at first row and first column, nanostructure R11″ at first row and second column, nanostructure L12″ at first row and third column, nanostructure R12″ at first row and fourth column, nanostructure L13″ at first row and fifth column, nanostructure R13″ at first row and sixth column, nanostructure L14″ at first row and seventh column and nanostructure R14″ at first row and eighth column. In the end, the eighth row includes: nanostructure L81″ at the eighth row and first column, nanostructure R81″ at eighth row and second column, nanostructure L82″ at eighth row and third column, nanostructure R82″ at eighth row and fourth column, nanostructure L83″ at eighth row and fifth column, nanostructure R83″ at eighth row and sixth column, nanostructure L84″ at eighth row and seventh column and nanostructure R84″ at eighth row and eighth column. As a result, the nanostructure Lmn“ (m and n are positive integer) formed on the first surface is located at m-th row and (2n-1)th column, and the nanostructure Rmn” (m and n are positive integer) formed on the first surface is located at m-th row and (2n)th column; wherein m is a positive integer from 1 to a, n is a positive integer from 1 to b/2, a is total number of rows, b is the total number of columns, and both a and b are even integer. When the light from an object is incident on the metalens, the propagation of light will be guided to different direction by the plurality of nanostructures. Depending on actual requirement of the design, each of the plurality of nanostructures can be designed to guide the light in any desired direction. The image sensing element 330 includes a sensing surface 3301 and a bottom surface. The sensing surface is further divided into a plurality of pixel areas; wherein, in the third embodiment of the invention, the number of rows of the pixel areas is equal to the number of rows of the nanostructures and the number of columns of the pixel areas is equal to the number of columns of the nanostructures. In the example of third embodiment, the sensing surface is divided into 8 rows in the horizontal direction, and the sensing surface is divided into 8 columns in the vertical direction. Therefore, the sensing surface is divided into a total of 64 (=8×8) pixel areas. As shown in FIG. 6, the first row 3301R1 of the sensing surface of the image sensing element 330, which is viewed from the bottom surface to the sensing surface (facing the object side) and is marked from left to right and top to bottom, includes: pixel area L11″″ at first row and first column, pixel area L12″ at first row and second column, pixel area L13″ at first row and third column, pixel area L14″″ at first row and fourth column, pixel area R11″″ at first row and fifth column, pixel area R12″″ at first row and sixth column, pixel area R13″ at first row and seventh column and pixel area R14″″ at first row and eighth column. In the end, the eighth row 3301R8 of the sensing surface includes: pixel area L81″ at the eighth row and first column, pixel area L82″′ at eighth row and second column, pixel area L83″ at eighth row and third column, pixel area L84″ at eighth row and fourth column, pixel area R81″″ at eighth row and fifth column, pixel area R82″″ at eighth row and sixth column, pixel area R83′″ at eighth row and seventh column and pixel area R84″ at eighth row and eighth column. As a result, the pixel area Lmn″″ (m and n are positive integer) formed on the sensing surface 3301 is located at m-th row and n-th column provided that n satisfies the condition: 1≤n≤d/2, and the pixel area Rmn″″ (m and n are positive integer) formed on the sensing surface 3301 is located at m-th row and n-th column provided that n satisfies the condition: d/2<n≤d; wherein m is a positive integer from 1 to c, n is a positive integer from 1 to d, c is total number of rows, d is the total number of columns, and both c and d are even integer. When the lens assembly in the third embodiment forms an image of an object, the optical path of the light from the object and passing through the metalens 310 is partly similar to the optical path in second embodiment. However, in the third embodiment of the invention, the light from the object and passing through the nanostructure L11″ at first row and first column on the metalens 310 is guided to the pixel area L11′″ at first row and first column on the sensing surface, the light from the object and passing through the nanostructure L12″ at first row and third column on the metalens 310 is guided to the pixel area L12″ at first row and second column on the sensing surface, the light from the object and passing through the nanostructure L13″ at first row and fifth column on the metalens 310 is guided to the pixel area L13″′ at first row and third column on the sensing surface, and the light from the object and passing through the nanostructure L14″ at first row and seventh column on the metalens 310 is guided to the pixel area L14″″ at first row and fourth column on the sensing surface. As a result, the light from the object and passing through the nanostructure located at the m-th row and (2n-1)th column is guided to the pixel area at m-th row and n-th column on the sensing surface; wherein m and n are positive integer, m is a positive integer from 1 to a, n is a positive integer from 1 to b/2, a is the total number of rows of the metalens, b is the total number of columns of the metalens, and both a and b are even numbers. In the third embodiment, a is equal to 8 which is a multiple of 4, b is equal to 8 which is a multiple of 4. Moreover, in the third embodiment of the invention, the light from the object and passing through the nanostructure R11″ at first row and second column on the metalens 310 is guided to the pixel area R11″′ at first row and fifth column on the sensing surface, the light from the object and passing through the nanostructure R12″ at first row and fourth column on the metalens 310 is guided to the pixel area R12″″ at first row and sixth column on the sensing surface, the light from the object and passing through the nanostructure R13″ at first row and sixth column on the metalens 310 is guided to the pixel area R13″ at first row and seventh column on the sensing surface, and the light from the object and passing through the nanostructure R14″ at first row and eighth column on the metalens 310 is guided to the pixel area R14″ at first row and eighth column on the sensing surface. As a result, the light from the object and passing through the nanostructure located at the m-th row and (2n)th column is guided to the pixel area at m-th row and (n+b/2)th column on the sensing surface; wherein m and n are positive integer, m is a positive integer from 1 to a, n is a positive integer from 1 to b/2, a is the total number of rows of the metalens, b is the total number of columns of the metalens, and both a and b are even numbers. In the end, the light from the object and passing through the nanostructure L81″ at eighth row and first column on the metalens 310 is guided to the pixel area L81″ at eighth row and first column on the sensing surface, the light from the object and passing through the nanostructure L82″ at eighth row and third column on the metalens 310 is guided to the pixel area L82′″ at eighth row and second column on the sensing surface, the light from the object and passing through the nanostructure L83″ at eighth row and fifth column on the metalens 310 is guided to the pixel area L83′″ at eighth row and third column on the sensing surface, the light from the object and passing through the nanostructure L84″ at eighth row and seventh column on the metalens 310 is guided to the pixel area L84″″ at eighth row and fourth column on the sensing surface, the light from the object and passing through the nanostructure R81″ at eighth row and second column on the metalens 310 is guided to the pixel area R81″ at eighth row and fifth column on the sensing surface, the light from the object and passing through the nanostructure R82″ at eighth row and fourth column on the metalens 310 is guided to the pixel area R82″ at eighth row and sixth column on the sensing surface, the light from the object and passing through the nanostructure R83″ at eighth row and sixth column on the metalens 310 is guided to the pixel area R83″″ at eighth row and seventh column on the sensing surface, and the light from the object and passing through the nanostructure R84″ at eighth row and eighth column on the metalens 310 is guided to the pixel area R84″″ at eighth row and eighth column on the sensing surface. Furthermore, in the third embodiment of the invention, the first surface of the metalens and the sensing surface of the sensor 330 are respectively divided into incident areas and sensing areas in matrix form, and the sensing areas of the sensor 330 are further divided into a first sensing area and a second sensing area. The first sensing area and second sensing area will form a left view and a right view image at the corresponding position of the object, or an upper view image at the corresponding position and a lower view image at the corresponding position of the object. After the light from an object is incident on and passing through the incident areas in matrix form, the light will be guided to each of the plurality of pairs of pixel areas in the sequence from left to right and top to down by each of the plurality of pairs of nanostructures correspondingly. Each pair of nanostructures respectively receives the left view at the corresponding position and right view at the corresponding position of light from the object, and then the left view at the corresponding position and right view at the corresponding position of light from the object and passing such pair of nanostructures will form the left view and right view image at the corresponding position of the object by a corresponding pair of pixel areas. In the third embodiment, the pixel areas in each pair are spaced apart so that one pixel area is formed on the first sensing area to be a first view pixel area and the other pixel area is formed on the second sensing area to be a second view pixel area. In accordance with the third embodiment, the first sensing area includes the pixel areas in the first columns to the fourth columns for receiving the left view image of the object and the second sensing area includes the pixel areas in the fifth columns to the eighth columns for receiving the right view image of the object. In this way, after the light from an object is incident on and passing through the nanostructures of the metalens 310, the light will be respectively guided to the first sensing area and second sensing area of the sensor 330. Therefore, the left view image and the right view image produced by the first sensing area and the second sensing area together form a stereoscopic image of the object having the feature of depth perception. The above description in the third embodiment does not limit the scope of the claims in the present invention. Similarly, the first sensing and the second sensing areas of the sensor 330 cooperate with the corresponding pair of nanostructures to form an upper view image and a lower view image of the object.

Regarding the lens assembly in the second and third embodiments, the incident area of the metalens and the sensing surface of the sensor are divided into a matrix of 8×8 areas. Nevertheless, the embodiments do not limit the scope of the claims in the invention and the incident area of the metalens and the sensing surface of the sensor can be divided into a matrix of K×K areas, wherein K is an even integer. Or, in the present invention, the incident area of the metalens and the sensing surface of the sensor can be divided into a matrix of KXL areas, wherein K is an even integer and L is an positive integer. For example, the incident area of the metalens and the sensing surface of the sensor can be divided into a matrix of 8×11 areas, 10×7 areas, 6×3 areas . . . etc. More specifically, the incident area can be divided into a total of even number of rows in the horizontal direction and divided into a total of positive integer number of columns in the vertical direction, and the sensing area can be divided into a total of even number of rows in the horizontal direction and divided into a total of positive integer number of columns in the vertical direction. In such circumstance of even number of rows, each pair of nanostructures is disposed on pair of rows in sequence in the vertical direction, and each pair of pixel areas is disposed on pair of row in sequence in the vertical direction. Similarly, in the present invention, the incident area of the metalens and the sensing surface of the sensor can be divided into a matrix of K×L areas, wherein K is an positive integer and L is an even integer. For example, the incident area of the metalens and the sensing surface of the sensor can be divided into a matrix of 9×12 areas, 11×16 areas, 13×24 areas . . . etc. More specifically, the incident area can be divided into a total of positive integer number of rows in the horizontal direction and divided into a total of even number of columns in the vertical direction, and the sensing area can be divided into a total of positive integer number of rows in the horizontal direction and divided into a total of even number of columns in the vertical direction. In such circumstance of even number of columns, each pair of nanostructures is disposed on pair of columns in sequence in the horizontal direction. In addition, at least one of the total number of rows and the total number of columns is an even integer.

In the first, second, and third embodiments, the pattern or structure of plurality of pairs of nanostructures may be rectangular, circular columns, elliptical, rhombus, cross, quadrilateral, pentagonal, hexagonal, octagonal, asymmetrical, the cross-sectional shape of an oak barrel, or all or part of the aforementioned shape, and each of the plurality of nanostructures can be designed to guide the light in any desired direction so that the light can be guided to a desired sensing area. The shape of the plurality of pairs of microstructures may all be the same. Or, the shape of the plurality of pairs of nanostructures may be partially the same and the shape of other pairs of nanostructures may be different.

In the first, second, and third embodiments, the pattern or structure of plurality of pairs of nanostructures can be manufactured by imprint or by semiconductor process.

Regarding the lens assembly in the first, second, and third embodiments, the size of the nanostructure of the metalens is about less than 5 nanometer; however, it does not limit the scope of the claims in the invention. Regarding the application of the lens assembly of the invention, the size of the nanostructure of the metalens may be 100 nanometer, 90 nanometer, 80 nanometer, 70 nanometer, 60 nanometer, 50, nanometer, 40 nanometer, 30 nanometer, 20 nanometer, 10 nanometer or 2 nanometer. Therefore, in the present invention, the size of the nanostructure of the metalens is between 1 nanometer and 99 nanometer.

Regarding the lens assembly in the first, second, and third embodiments, the nanostructures of the metalens can be formed on the first surface facing the object side, on the second surface facing the image side, or on both first surface and second surface. In addition, the metalens in the illustration may be composed of one metalens or a combination of multiple metalenses. The arrangement of the patterns or structure of the nanostructures may be in sequential order, in a staggered order, or in random order. The arrangement of the patterns or structure of the nanostructures may be partially in sequential order and partially in staggered order. The arrangement of the patterns or structure of the nanostructures may be partially in sequential order and partially in random order. Furthermore, the arrangement of the patterns or structure of the nanostructures may be partially in sequential order, partially in staggered order, and partially in random order.

In the present invention, if the total number of columns is an even number, the total number of rows may be either an odd number or even number.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A lens assembly, in sequence from an object side to an image side, comprising:
an optical element comprising a plurality of pairs of nanostructures; and
an image sensing element comprising a plurality of pairs of pixel areas;
wherein each pair of nanostructures comprises a first view nanostructure and a second view nanostructure;
wherein each pair of pixel areas comprises a first view pixel area and a second view pixel area; and
wherein the first view nanostructure guides a light from the object to form an image of the object on the first view pixel area and the second view nanostructure guides a light from the object to form an image of the object on the second view pixel area.

2. The lens assembly as claimed in claim 1, wherein:
the first view nanostructure and the second view nanostructure are adjacent to each other to form a pair of nanostructures; and
all the pairs of nanostructures are arranged in sequence to form a plurality of pairs of nanostructures.

3. The lens assembly as claimed in claim 2, wherein:
the first view pixel area and the second view pixel area are adjacent to each other to form a pair of pixel areas; and
all the pairs of pixel areas are arranged in sequence to form a plurality of pairs of pixel areas.

4. The lens assembly as claimed in claim 2, wherein:
the first view pixel area and the second view pixel area are spaced at regular interval to form a pair of pixel areas; and
all pairs of pixel areas are arranged in periodic order to form a plurality of pairs of pixel areas.

5. The lens assembly as claimed in claim 1, wherein:
the first view nanostructure and the second view nanostructure are spaced at regular interval to form a pair of nanostructures; and
all pairs of nanostructures are arranged in periodic order to form a plurality of pairs of nanostructures.

6. The lens assembly as claimed in claim 5, wherein:
the first view pixel area and the second view pixel area are spaced at regular interval to form a pair of pixel areas; and
all pairs of pixel areas are arranged in periodic order to form a plurality of pairs of pixel areas.

7. The lens assembly as claimed in claim 1, wherein:
the pattern or structure of first view nanostructure and the second view nanostructure is the same or different; and
the size of the first view nanostructure and the second view nanostructure is the same size or different.

8. The lens assembly as claimed in claim 1, claim 2 or claim 5, wherein:
the optical element comprises a first surface facing the object side and a second surface facing the image side;
the image sensing element is a sensor comprising a sensing surface facing the object side and a plurality of pairs of pixel areas is formed on the sensing surface; and
after a light from the object side passing through the first view nanostructure is guided to the first view pixel area and a light from the object side passing through the second view nanostructure is guided to the second view pixel area.

9. The lens assembly as claimed in claim 8, wherein:
the first surface of the optical element is divided into a first incident area facing the object side and a second incident area facing the object side;
the image sensing element is divided into a first sensing area facing the object side and a second sensing area facing the object side;
the first incident area and the second incident area are divided into a total number of “a” rows in the horizontal direction and divided into a total number of “b” columns in the vertical direction so that a total of incident areas are “a” times “b”, wherein “a” is a positive integer greater than or equal to 2, “b” is a positive integer greater than or equal to 1, or “a” is a positive integer greater than or equal to 1, “b” is a positive integer greater than or equal to 2, and each incident area includes its nanostructure; and
the first sensing area and the second sensing area are divided into a total number of rows which equal to the number of rows of the incident area in the horizontal direction and divided into a total number of columns which equal to the number of columns of the incident area.

10. The lens assembly as claimed in claim 9, wherein:
after the light from the object is incident on the incident area of the m-th row and the n-th column, it is guided to the corresponding sensing area of the m-th row and the n-th column, wherein the “m” is a positive integer from 1 to a, and the “n” is a positive integer from 1 to b.

11. The lens assembly as claimed in claim 9, wherein:
after the light from the object is incident on the incident area of the m-th row and the (2n-1)th column, it is guided to the sensing area of the m-th row and n-th column, the “m” is a positive integer from 1 to a, and the “n” is a positive integer from 1 to b/2; and
wherein after the light from the object is incident on the incident area of the m-th row and the 2n-th column, it is guided to the sensing area of the m-th row and (b/2+n)th column, the “m” is a positive integer from 1 to a, and the “n” is a positive integer from 1 to b/2.

12. The lens assembly as claimed in claim 10 or claim 11, wherein the number of columns in the incident area is equal to the number of columns in the sensing area, the number of rows in the incident area is equal to the number of rows in the sensing area.

13. The lens assembly as claimed in claim 8, wherein:
the pattern of plurality of pairs of nanostructures is selected from at least one of the group of rectangular, circular columns, elliptical, rhombus, cross, quadrilateral, pentagonal, hexagonal, octagonal, asymmetrical, the cross-sectional shape of an oak barrel.

14. The lens assembly as claimed in claim 13, wherein the shape of the plurality of pairs of microstructures may all be the same.

15. The lens assembly as claimed in claim 13, wherein the shape of the plurality of pairs of nanostructures is partially the same and the shape of other pairs of nanostructures is different.

16. The lens assembly as claimed in claim 13, wherein the arrangement of the patterns is in sequential order, in a staggered order, or in random order.

17. The lens assembly as claimed in claim 13, wherein the arrangement of the patterns is partially in sequential order and partially in staggered order.

18. The lens assembly as claimed in claim 13, wherein the arrangement of the patterns is partially in sequential order and partially in random order.

19. The lens assembly as claimed in claim 13, wherein the arrangement of the patterns is partially in sequential order, partially in staggered order, and partially in random order.

20. The lens assembly as claimed in claim 8, wherein:
the plurality of pairs of nanostructures are disposed on the first surface and the second surface, or the plurality of pairs of nanostructures are disposed either on the first surface or on the second surface.

21. The lens assembly as claimed in claim 1, wherein:
the optical element includes a first surface facing an object side and a second surface facing an image side, at least one of the first and second surfaces is divided into a plurality of rows in the horizontal direction and a plurality of columns in the vertical direction so as to form a plurality of pair of nanostructures, wherein each pair of nanostructures comprises a first view nanostructure and a second view nanostructure;
the sensing surface of the image sensing element is divided into a plurality of rows in the horizontal direction and a plurality of columns in the vertical direction so as to form a plurality of pair of pixel areas, wherein each pair of pixel areas comprises a first view pixel area and a second view pixel area; and
after the light from the object is incident on the plurality of pair of nanostructures, the light is guided to the first view pixel area by the first view nanostructure and the light is guided to the second view pixel area by the second view nanostructure.

22. The lens assembly as claimed in claim 21, wherein:
the first view pixel area and the second view pixel area are adjacent to each other to form a pair of pixel areas; and
at least one of the total number of rows and the total number of columns is an even integer.

23. The lens assembly as claimed in claim 21, wherein:
the first view pixel area and the second view pixel area are spaced at regular interval to form a pair of pixel areas; and
at least one of the total number of rows and the total number of columns is an even integer.
